(19) United States
(12) Patent Application Publication
(10) Pub. No.: US 2006/0131268 A1
(43) Pub. Date: Jun. 22, 2006

(54) Non-contact discrete removal of substrate surface contaminants/coatings, and method, apparatus, and system for implementing the same

(75) Inventors: Katrina Mikhaylichenko, San Jose, CA (US); Vladislav Yakovlev, Milwaukee, WI (US); Michael Ravkin, Sunnyvale, CA (US); John M. de Larios, Palo Alto, CA (US); Fritz C. Redeker, Fremont, CA (US)

Correspondence Address: MARTINE PENILLA & GENCARELLA, LLP, 710 LAKEWAY DRIVE, SUITE 200, SUNNYVALE, CA, 94085, US

(73) Assignee: LAM RESEARCH CORP., Fremont, CA (US)

(21) Appl. No.: 11/020,431

(22) Filed: Dec. 21, 2004

(51) Int. Cl. C23F 1/00; H01L 21/306; B44C 1/22; C03C 15/00

(52) U.S. Cl. 216/62; 156/345.5; 216/65

(57) ABSTRACT

A substrate preparation method is provided. The method includes providing a substrate to be prepared. The substrate has a first layer and a second layer. The first layer is to be removed from over the second layer. An energy frequency that is to be absorbed by the second layer while penetrating through the first layer transparently is determined. Energy that has the determined energy frequency is applied onto the first layer so as to disrupt a bond between the first layer and the second layer at a location of application of the energy. A portion of the first layer defined at the location of application of energy is removed. A substrate preparation apparatus is also provided.

### BACKGROUND

1. Field of the Invention

The present invention relates generally to substrate preparation and cleaning, and more particularly, to systems, apparatus, and methods for improving substrate preparation and/or cleaning operations.

2. Description of the Related Art

The fabrication of semiconductor devices involves numerous processing operations. These operations include, for example, dopant implants, gate oxide generation, inter-metal oxide depositions, metallization depositions, photolithography patterning, etching operations, chemical mechanical polishing (CMP), etc. Some processing operations may include removing of an entire layer of film/coating or a discrete portion of the film/coating from over the wafer surfaces. Other processing operations may include generating particulate contaminants, which can typically adhere to wafer surfaces. Generally, particulate contaminants consist of tiny bits of distinctly defined material having an affinity to adhere to the surfaces of the wafer. Examples of particulate contaminants can include organic and inorganic residues, such as silicon dust, silica, slurry residue, polymeric residue, metal flakes, atmospheric dust, plastic particles, and silicate particles, among others. Failure to remove a desired layer or the particulate contaminants from wafer surfaces can have detrimental effects on the performance of integrated circuit devices.

Cleaning wafer surfaces and removing the particulate contaminants and/or films or coatings can be achieved using non-contact laser cleaning techniques. In conventional laser cleaning systems, an Ultra Violet (UV) light beam is issued by a laser system and shined onto the wafer surface. The energy supplied by the UV light beam is then used to break the bond between the particulate contaminants/coatings/films and wafer surface. The particulate contaminants or portions of the coatings/films detached from wafer surfaces are then evaporated. In photoablation, one of such conventional non-contact cleaning techniques, UV light beams having 355 to 550 nanometer wavelengths and pulse durations of about seven (7) to ten (10) nanoseconds are implemented.

Several drawbacks can be associated with using the energy generated in the conventional laser cleaning systems. One of such limitations is the fairly difficult to control nature of the photoablation processes. By way of example, thermal processes cause the material of the particulate contaminants/film/coating to be evaporated layer by layer, starting from the very top surface of the particulate contaminants/film/coating. However, because thermal processes are hard to manage, the wafer surface defined directly underneath the location of the removed particulate contaminants/film/coating can be damaged. Additionally, the rather hard to control nature of the thermal processes can further damage the edges of the remaining film/coating surrounding the locally detached and removed portions. As such, thermal processes can be unsuitable for precise and discrete removal of the particulate contaminants or portions of films/coatings.

Yet another limitation associated with the conventional laser cleaning systems is the rather narrow range of UV light beam intensities (i.e., energy) supported by the typical laser systems suitable for removal of the particulate contaminants/films/coatings from the wafer surface. In particular, removing particulate contaminants/films/coatings strongly bonded to the wafer surfaces requires high UV light beam intensity laser pulses. However, again, implementing high intensity UV light beams can damage the wafer surface defined directly underneath the location of the detached particulate contaminant or the removed portion of film or coating.

Still another limitation is that the conventional laser systems are used in conjunction with custom gas recipes. However, to achieve effective cleaning, complicated and expensive gas recipes should be obtained and implemented.

Limitations associated with conventional laser cleaning systems can be understood by the four scanning electron microscopy (SEM) images associated with four stages of removing a silicon oxide film from over a silicon wafer, as depicted in FIGS. 1A-1D. As shown, the silicon oxide layer is being irradiated with nanosecond UV light beam laser pulses at four different energy densities. FIG. 1A depicts a UV light beam having a 355 nanometer wavelength (produced by the third harmonic of the Nd: YAG laser system) and a pulse duration of eight (8) nanoseconds. In FIG. 1A, the supplied energy falls about 30 percent below the threshold of energy required to break the bond between the silicon oxide film and the silicon wafer. As shown, no changes have been made to the silicon oxide film. FIG. 1B shows a UV light beam having the 355 nm wavelength and a pulse duration of eight (8) nanoseconds supplying energy falling 10 percent below the threshold of energy required to break the bond. As can be seen, bubbles have been formed in the silicon oxide film. However, although the silicon oxide film has been damaged so some extent, the silicon oxide film has remained intact. The SEM illustrated in FIG. 1C depicts a UV light beam having a 355 nanometer wavelength and a pulse duration of eight (8) nanoseconds supplying energy falling 10 percent above the threshold energy. As can be seen, while a portion of the silicon oxide film has been detached and removed, only bubbles have been formed in the remaining silicon oxide film. Additionally, the remaining film surrounding the removed portion of the silicon oxide film has sharp and irregular edges. FIG. 1D illustrates the SEM of a UV light beam having a 355-nanometer wavelength and a pulse duration of eight (8) nanoseconds supplying energy falling about 30 percent above the energy threshold. As can be seen, the silicon surface defined directly underneath the removed portion of the silicon oxide film has been damaged.

Accordingly, the nanosecond conventional laser cleaning systems can damage wafer surfaces being prepared. Such damages are disfavored as the condition of the wafer surfaces and the operation of the wafers can be adversely affected, ultimately lowering the process yield.

In view of the foregoing, there is a need for a system, apparatus, and method for preparing substrate surfaces capable of locally removing particulate contaminants, films, and coatings from over surfaces of the substrates without substantially damaging substrate surfaces.

### SUMMARY OF THE INVENTION

Broadly speaking, the present invention fills these needs by providing a method, apparatus, and system capable of precise, discrete, and local removal of particulate contaminants, films, and coatings from over a surface of a substrate without substantially damaging the substrate surface. In one embodiment, high intensity ultra short laser beam pulses are implemented to locally remove the particulate contaminants, films, and coatings from over a surface. It should be appreciated that the present invention can be implemented in numerous ways, including as a process, an apparatus, a system, a device, or a method. Several inventive embodiments of the present invention are described below.

In one embodiment, a substrate preparation method is provided. The method includes providing a substrate to be prepared. The substrate has a first layer and a second layer. The first layer is configured to be removed from over the second layer. An energy frequency that is to be absorbed by the second layer while penetrating through the first layer transparently is determined. Energy that has the determined energy frequency is applied onto the first layer so as to disrupt a bond between the first layer and the second layer at a location of application of the energy. A portion of the first layer defined at the location of application of energy is removed.

In another embodiment, a substrate preparation apparatus is provided. The apparatus includes an energy source and a support component. The energy source is capable of emitting energy emitted in a femtosecond pulse duration onto a substrate to be prepared. The substrate has a first layer and a second layer wherein the first layer is configured to be removed from over the second layer. The energy is configured to have an energy frequency that is capable of being absorbed by the second layer while transparently penetrating through the first layer. The support component is configured to support the substrate to be prepared as energy is emitted onto the first layer of the substrate. The absorption of the energy by the second layer generates an energy wave that is capable of breaking a bond between the first layer and the second layer at a location of application of the energy so as to remove a portion of the first layer at the location of the application of the energy.

In yet another embodiment, another substrate preparation method is provided. An energy frequency that is configured to be absorbed by a substrate surface while transparently penetrating through a particulate contaminant adhered to the substrate surface is determined. Energy that has the determined energy frequency is applied onto the particulate contaminant so as to disrupt a bond between the particulate contaminant and the substrate surface.

The advantages of the present invention are numerous. Most notably, in contrast to the prior art, the embodiments of the present invention enable precise, discrete, and localized cleaning of substrate surfaces while substantially minimizing damages the substrate surface. Another advantage of the non-contact femtosecond laser system of the present invention is that the system can be implemented to prepare fragile materials. Yet another advantage of the present invention is that the non-contact femtosecond laser system of the present invention can be efficiently used to prepare substrate surfaces, thus maximizing throughput. Still another advantage of the non-contact laser system of the present invention is the capability of the system to perform dry-only cleaning of the substrate surfaces, thus enabling cleaning of materials that may be incompatible with wet chemistries. Yet another advantage of the present invention is that the localized, discrete, and precise removal capability of the present invention yields remaining films/coatings that have featureless featureless edges.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings, and like reference numerals designate like structural elements.

FIG. 1A depicts an SEM image illustrating a 355-nanometer UV light beam supplying energy falling 30 percent below the threshold energy required to break the bond between the silicon oxide film and silicon substrate.

FIG. 1B depicts an SEM image illustrating a 355-nanometer UV light beam supplying energy falling 10 percent below the threshold energy required to break the bond between the silicon oxide film and silicon substrate

FIG. 1C depicts an SEM image illustrating a 355-nanometer UV light beam supplying energy falling 10 percent above the threshold energy required to break the bond between the silicon oxide film and silicon substrate

FIG. 1D depicts an SEM image illustrating a 355-nanometer UV light beam supplying energy falling 30 percent above the threshold energy required to break the bond between the silicon oxide film and silicon substrate

FIG. 2A is a simplified cross-sectional view of an exemplary substrate preparation system implementing an exemplary high intensity ultra short laser beam pulse apparatus, in accordance with one embodiment of the present invention.

FIG. 2B is a simplified cross section view illustrating the precise, discrete, and localized removal capability of the femtosecond laser system of the present invention, in accordance with another embodiment of the present invention.

FIG. 2C is a simplified exaggerated cross-sectional view illustrating the precise, discrete, and localized removal capabilities associated with the high intensity femtosecond laser beam system, in accordance with still another embodiment of the present invention.

FIG. 2D depicts an SEM image illustrating the smooth edges of a portion of a silicon oxide layer having been removed with a single pulse of the femtosecond laser system, in accordance with still another embodiment of the present invention.

FIG. 2E depicts an SEM image illustrating the smooth edges of a portion of a silicon oxide layer having been removed with a single pulse of the femtosecond laser system having an energy density three times as much as the energy density of the laser beam depicted in FIG. 2D, in accordance with still another embodiment of the present invention.

FIG. 2F is a simplified top view of substrate surface illustrating the discrete removal of portions of the first layer with non-overlapping laser beam spots, in accordance with still another embodiment of the present invention.

FIG. 2G is a simplified top view of substrate surface illustrating the discrete removal of portions of the first layer with overlapping laser beam spots, in accordance with still another embodiment of the present invention.

FIG. 3A is a simplified cross sectional view of an exemplary high intensity ultra short pulse laser apparatus implementing diffractive optics, in accordance with still another embodiment of the present invention.

FIG. 3B is a simplified top view of the substrate being processed using the diffractive laser beams shown in FIG. 3A, in accordance with still another embodiment of the present invention.

FIG. 4 is a simplified cross sectional view of an integrated laser surface inspection and particulate contaminant/film/coating removal apparatus, in accordance with still another embodiment of the present invention.

### DETAILED DESCRIPTION

An invention that is capable of precisely and discretely removing particulate contaminants, films, and coatings from over surfaces of the substrate without substantially damaging substrate surfaces is provided. In one embodiment, high intensity ultra short laser beam pulses issued by a laser system is implemented to break a bond between the particulate contaminants/films/coatings and the substrate surface leading to the removal of the particulate contaminants, films, and coatings from over substrate surfaces. According to one example, an irradiation wavelength of the laser beam is selected such that the laser beam can be absorbed completely by the substrate while is absorbed minimally (if any) by the particulate contaminants/films/coatings being removed. In one example, the laser beam pulse duration can range between about one (1) femtosecond and 100,000 femtoseconds. In the following description, numerous specific details are set forth in order to provide a thorough understanding of the present invention. It will be understood, however, to one skilled in the art, that the present invention may be practiced without some or allof these specific details. In other instances, well known process operations have not been described in detail in order not to unnecessarily obscure the present invention.

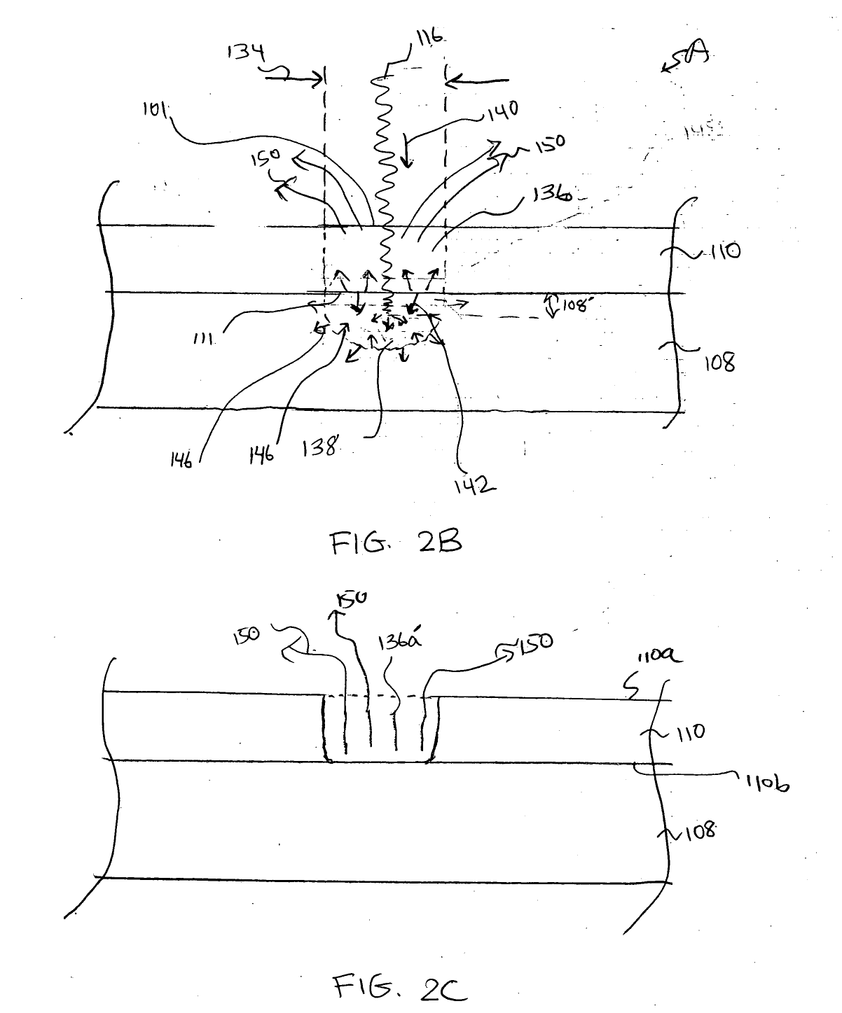

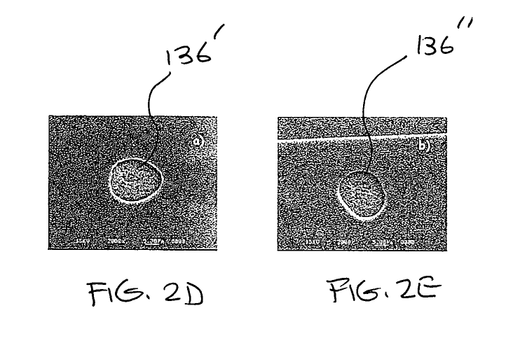

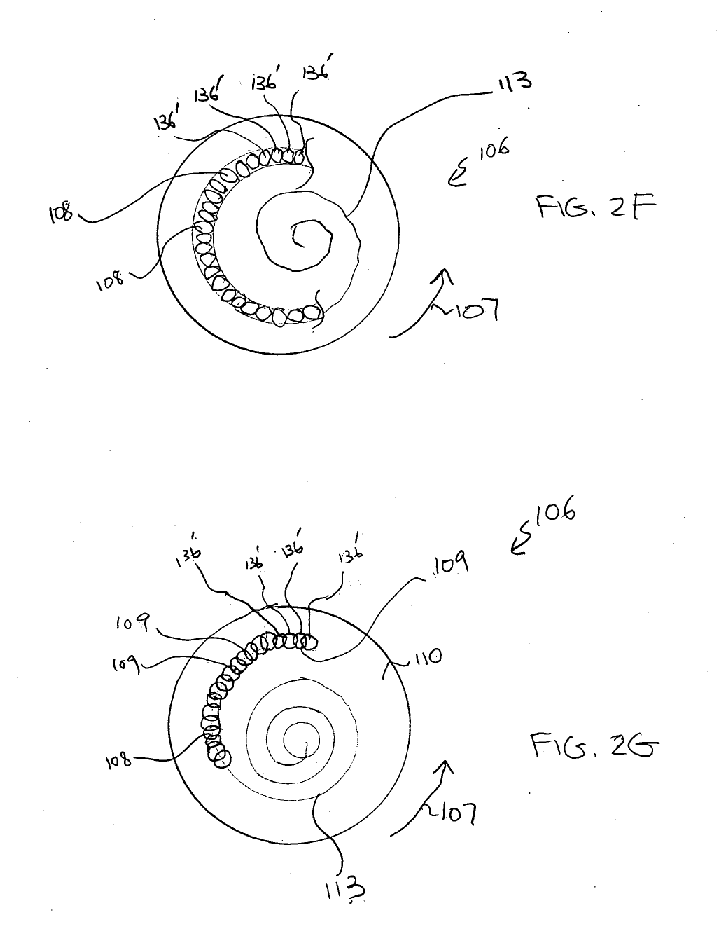

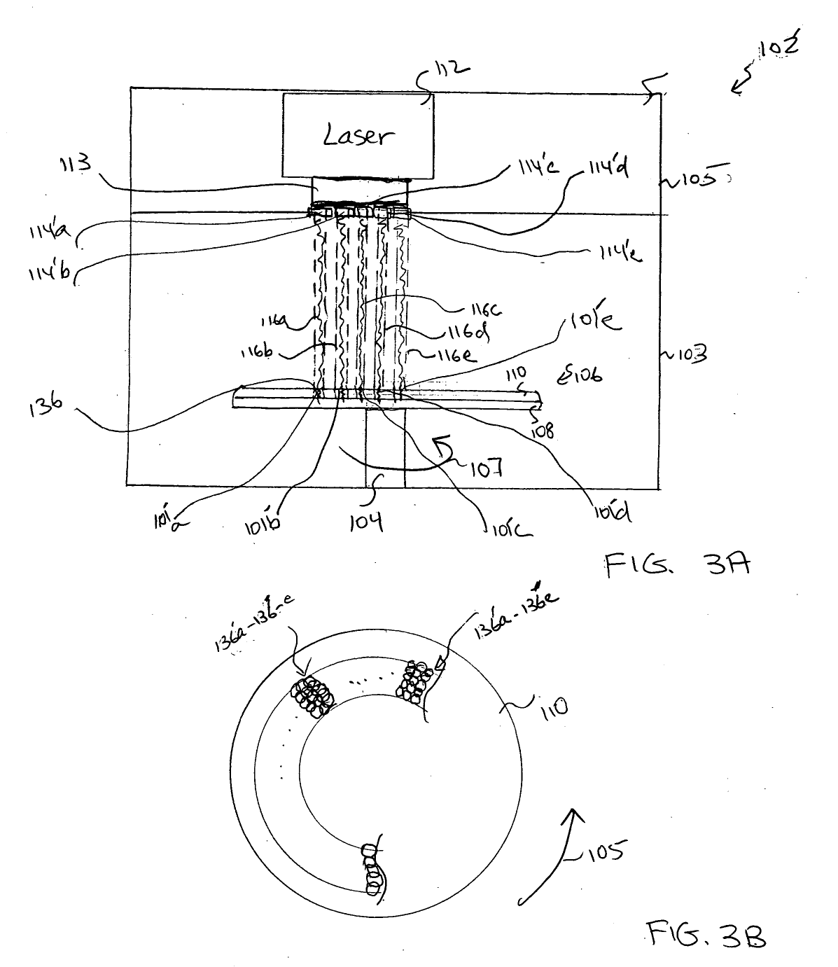

FIG. 2A depicts an exemplary substrate preparation system 100 implementing an exemplary high intensity ultra short laser beam pulse apparatus 102, in accordance with one embodiment of the present invention. According to one embodiment, “ultra short pulse” can be in femtoseconds. For instance, the ultra short pulse can range between about one (1) femtosecond and 100,000 femtoseconds. As such, for ease of reference, the ultra short laser beam pulses are referred to as “femtosecond pulses” and the high intensity ultra short laser beam pulse apparatus is referred to as a femtosecond apparatus. However, references to femtosecond may not limit the ultra short laser beam pulse duration, as referred herein. The substrate preparation system 100 includes the apparatus 102, system controller 118, and gas supply component 120. The apparatus 102 is comprised of a chamber 103 and a top component 105 placed above a top wall 103a of the chamber 103. A stage 104 is disposed on a bottom wall 103b of the chamber 103 and is configured to support and rotate a substrate to be prepared 106 in a rotation direction 107 during substrate preparation operations. As will be described in more detail below, in accordance with one embodiment of the present invention, an entire first layer 110 of the substrate 106 can be stripped from over the second layer 108 using the femtosecond apparatus of the present invention. In another embodiment, a portion of the first layer 110 can be removed from over the bottom layer 108 using the precise, discrete, and localized removal capabilities provided by the high intensity femtosecond apparatus of the present invention.

The top component 105 houses a laser system 112 implementing an optic 114. A laser beam 116 issued by the laser system 112 is shined over a spot 101 on the substrate 106 so as to scan and ultimately strip the first layer 110, as the substrate 106 is translationally rotated in the rotation direction 107. Of course, one of ordinary skill in the art must appreciate that although in the illustrated embodiment the substrate 106 and stage 104 have been placed in the translational and rotation states, in another embodiment, the laser system 112 can be set on a scanning state so as to move in a scanning direction, thus scanning the entire surface of the substrate 106, as the stage 104 and the substrate 106 remain stationary while rotating. One of ordinary skill in the art must further appreciate that in a different embodiment, the substrate surface 106 can be scanned using the optics 114 while the laser system 112 remains stationary. For instance, an angle of the optics can be changed so as to shine the laser beam 116 at different spots on the substrate 106, scanning the entire substrate surface.

One of ordinary skill in the art must appreciate that the stage 104 can be rotated and moved translationally using any appropriate mechanism. Yet further, one of ordinary skill in the art must appreciate that while in the illustrated embodiment the substrate 106 is supported and rotated by the stage 104, in another embodiment, any appropriate mechanics and engineering can be implemented to support, rotate, and move the substrate translationally (e.g., edge carrier, edge drive rotation rollers, vacuum chuck, etc.). Furthermore, in another embodiment, the position of the laser beam on the substrate 106 can be raster scanned by a set of mirrors and/or lenses.

In accordance with one embodiment, the laser system 112 is a Ti:Sapphire femtosecond laser system, and is used to provide laser beams of a desired wavelength (e.g., 800 nanometers, etc.). In one example, the Ti-Sapphire laser is a Ti-Sapphire Newport Corporation (the Spectra-Physics, Ltd.), located in Mountain view, Calif.

As will be described in more detail below with respect to FIGS. 2B-2G, as the first layer 110 is being stripped, materials resulting from removing the portions of the first layer 110 are released within the chamber 103 and mixed with the air or gas defined within the chamber 103. In the illustrated embodiment, the gas supply component 120 is configured to supply adequate gas flow into the chamber 103 via tube 122 and through conduits 124, 126, and 128 extending between a top surface 105a and bottom surface 105b of the top component 105. According to one implementation, as the gas is introduced into the chamber 103, the released materials 115 are moved downwardly within the chamber 103. The released materials 115 as well as the gas flow are ultimately expelled from the chamber 103 through exhausts. 131 defined in sidewalls 103b of the chamber 103 and eventually to exhaust pipes 130 disposed outside of the chamber 103. In this manner, the environment within the chamber 103 is maintained clean while the top layer 110 of the substrate 106 is being stripped using the precise, discrete, and localized removal capabilities of the femtosecond apparatus of the present invention.

As can be seen, in one instance, the exhausts 131 are fitted within respective pairs of seals 132 disposed in close proximity to exhausts 131. In this manner, advantageously, the seals 132 can prevent introduction of excess particulate contaminants into the chamber 103. In one embodiment, the gas introduced into the chamber 103 can be air or nitrogen. Of course, one of ordinary skill in the art must appreciate that any appropriate inert gas may be utilized to provide airflow within the chamber 103 and to expel released materials 115 from the chamber 103.

With continued reference to FIG. 2A, in the illustrated embodiment, the system controller 118 is configured to monitor the rotational and translational movements of the stage 107 and introduction of gas flow within the chamber 103. The system controller 118 is further configured to control the operation of the laser system 112, application of laser beams, and the irradiation wavelengths as well as irradiation intensities of the laser beams during operation.

As is described in more detail with respect to FIGS. 2B through 4, one of ordinary skill in the art must understand and appreciate that the principles of the present invention as described herein can be equally applied to remove contaminate particulates of different materials and properties as well as films and coatings having different materials and properties. However, for purposes of discussion and ease of reference, FIGS. 2A-2G have been described with a greater emphasis on the exemplary substrate 106 having a silicon oxide first layer 110 and a silicon second layer 108. Nonetheless, such references should not be considered limiting as described in more detail below.

FIG. 2B illustrates precise, discrete, and localized removal of the first layer 110 of the substrate 106 as a result of shining the ultra short laser beam pulse 116 onto the spot 101, in accordance with one embodiment of the present invention. In the illustrated embodiment, the wavelength of the laser beam 116 has been selected so as to be easily absorbable by the second layer 108 while being absorbed minimally by the first layer 110. Preferably, the laser beam 116 is configured to travel through the first layer 110 without being substantially absorbed. The laser beam 116 is shown to have been absorbed by the second layer 108 after the laser beam 116 has only traveled a short distance of 108′ within the second layer 108, in accordance with the absorption coefficient of the second layer (e.g., silicon, etc.).

In one example, absorption of the laser beam 116 by the second layer 108 results in a localized heating, causing a second layer active region 138 defined at an interface 111 of the first layer 110 and the second layer 108 to heat up locally. As can be seen, the second layer active region 138 is confided within a diameter of the spot 101. The second layer active region 138 is excited, heated up substantially rapidly, and expanded substantially rapidly. The heat can dissipate fast, causing the active region 138 to compress, giving rise to a stress wave 146 between the first layer 110 and the second layer 108 at the bond interface 111. In one example, a bipolar wave front 142 can be formed at the bond interface 111 when the stress wave reflects off a free surface (e.g., the interface between the first layer 110 and air, as confined within the diameter of the spot 101). In the event the energy of the stress wave 146 is greater than the tensile energy between the first layer 110 and the second layer 108 at the bond interface 111, the energy of the stress wave breaks the bond between the first layer 110 and the second layer 108 at the bond interface 111. As a consequence, the portion 136 of the first layer confided within the diameter of the spot 101 is detached and stripped off. According to one embodiment of the present invention, photospallation technique is implemented to break the forces between the contaminant particulates/films/coatings.

In one example, the pulse duration of the ultra short laser beam is configured to be shorter than a relaxation time of the material of the second layer 108. Thus, when the first layer is silicon oxide and the second layer is silicon, the pulse duration of the ultra short laser beam is about 70 femtoseconds. Additionally, the wavelength of the ultra short light beam is selected such that the laser beam 116 is absorbed by the silicon layer but not by the silicon oxide layer. In one example, the laser beam wavelength is about 800 nanometers. In one embodiment, the force created as a result of rapid expansion of the active region of the second layer is proportional to the power of the laser beam. By way of example, the shorter the laser beam pulse is, the faster the active region expands and thus the stronger the force breaking the bond between the particulate contaminants/films/coatings can be.

Precise, discrete, and localized removal capabilities associated with the high intensity femtosecond laser beam system can further be understood with respect to the localized removal of the portion 136 as illustrated in the exaggerated partial cross sectional view of FIG. 2C, in accordance with one embodiment of the present invention. As can be seen, the portion 136 of the first layer 110 has ultimately been stripped as shown by a removed portion 136′.

In the illustrated embodiment, removal of the portion 136 is achieved by removing the material in a removal direction 150, from a bottom surface 110bof the first layer 110 to a top surface 110a of the first layer 110. Ultimately, the material defined in the portion 136 is evaporated and thereafter removed from the chamber 103 by the airflow. In the illustrated embodiment, the remainder of the first layer 110 surrounding the removed portion 136′ is shown to have rather smooth edges. Of course, one of ordinary skill in the art must appreciate that localize removal capability of the present invention is substantially different than the prior art laser systems wherein the contaminants are removed layer by layer, starting from the top layer of the contaminant particulates toward the bottom layer of the contaminant.

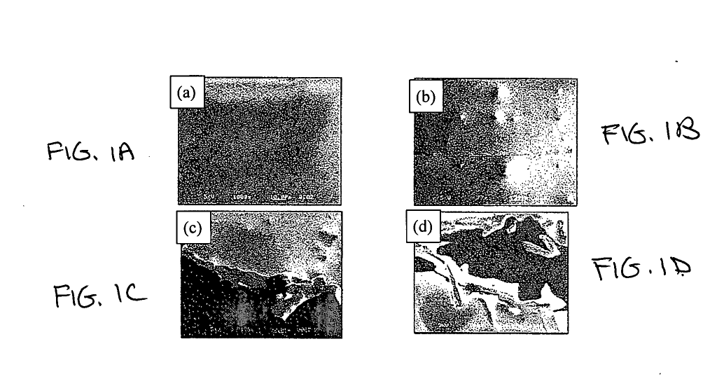

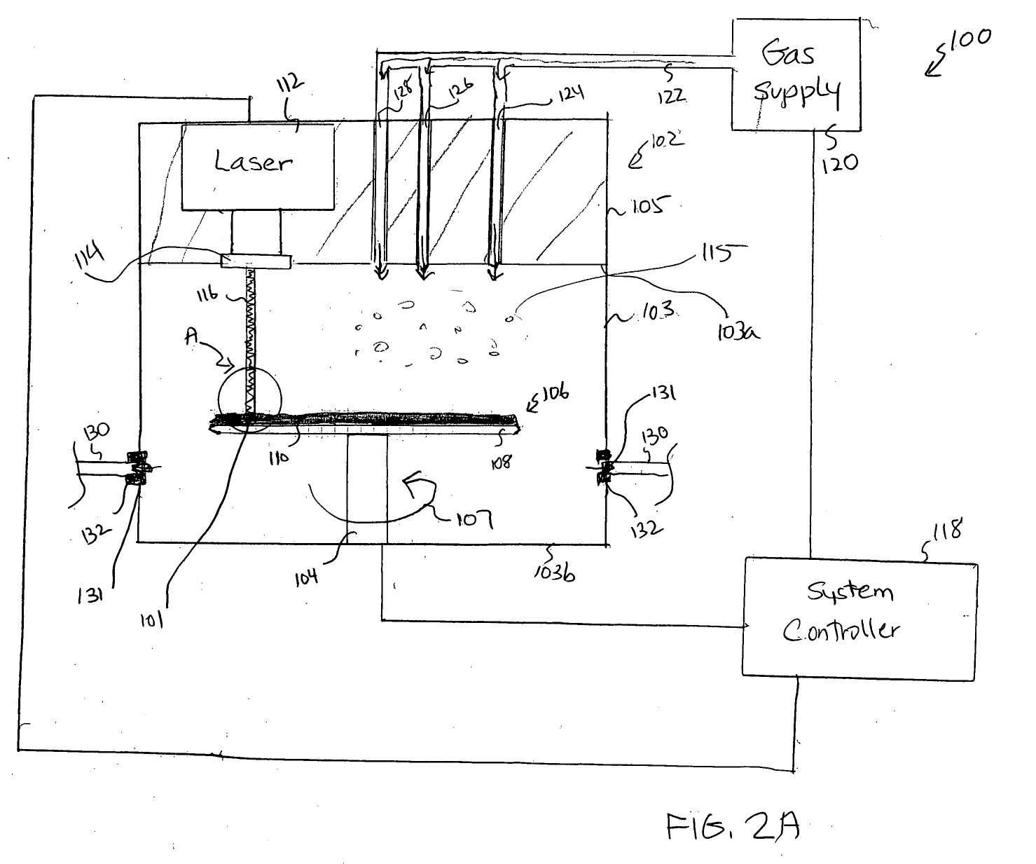

The SEM images shown in FIGS. 2D and 2E illustrate the precise, discrete, and localized removal capabilities of the present invention, in accordance with one embodiment of the present invention. As shown, a portion of the silicon oxide layer has been removed from over a silicon substrate using femtosecond laser pulses (i.e., ultra short laser beam pulses) having respective energy densities of approximately 0.3 J/cm² and approximately 0.1 J/cm². In the illustrated embodiment, laser beams having respective diameters of about 5 microns have been shined over the substrate surface, locally. Each of the removed portions 136′ and 136″ are shown to have smooth edges. In the same manner, the edges of the remaining silicon oxide layers surrounding the removed portions 136′ and 136 ″ are shown to be featureless. This is in contrast to the prior art laser system cleanings, as shown in SEM images in FIGS. 1A-1D, wherein the remaining layer surrounding the removed portion of the layer has sharp edges.

Although the diameters of the laser beams are about 5 microns, the energy density of the laser beam illustrated in FIG. 2D is greater than the energy density of the laser beam illustrated in FIG. 2E by a factor of three (3). However, as illustrated, increasing the energy density of the laser beam by the factor of there has not damaged the remaining silicon oxide layer surrounding the removed portion 136′. One must note that in the exemplary embodiments shown in FIGS. 2D and 2E, the photon energy of each laser beam is about 800 nanometers as opposed to the 355-nanometer wavelength conventionally implemented. According to one example, the power of the laser beam is directly proportional to the photon energy and inversely proportional to the duration of the pulse. Thus, dividing the photon energy in Joules by the time of pulse duration in femtoseconds can achieve a difference in the order of five (5) in the laser beam power with respect to a nanosecond pulse. One must further note that the laser beam power can be related to the characteristics of the laser beam as well as the energy of each photon (i.e., the wavelength of the photon) and the number of photons. Accordingly, in one example, reducing the pulse duration from 10 nanoseconds to 70 femtosecond (i.e., ultra short pulse duration) results in a significant increase in the laser beam power. Additionally, as the energy of each photon is decreased (i.e., wavelength of each photon is reduced), the amount of damage done by each photon is also reduced.

Furthermore, the removed portions of the first layer can produce particulate contaminants that can be deposited back on the removed portions of the first layer or a different location on the first layer. In the prior art with nanosecond laser beam systems, the deposited back contaminant particulates can be removed by increasing the energy of the laser beam. However, such increase in the laser beam energy can damage the portion of the second layer defined directly underneath the contaminant particulate. In the present invention, however, the deposited back contaminant particulates can be removed from over substrate using the high intensity ultra short laser beam pulses without substantially damaging the layer defined directly below the contaminant particulate.

Discrete removal of portions of the first layer 110 have been illustrated in the simplified top views of the substrate 106 depicted in FIGS. 2F and 2G, in accordance with one embodiment of the present invention. As illustrated, the material of the first layer 110 is removed from over the second layer 108 in a spiral manner 113, until the entire substrate surface is covered. In the embodiment shown in FIG. 2F, each of the removed portions 136′ of the first layer 110 is associated with a femtosecond laser beam pulse issued by the laser system 112. As shown, none of the removed portions 136′ overlap one another at any point. Comparatively, in the embodiment shown in FIG. 2G, the laser beam pulses 116 have been issued on the substrate 106 such that the removed portions 136′ overlap with one another forming overlapped regions 109. In another embodiment, the femtosecond laser beam pulses can be issued such that multiple femtosecond laser beam pulses are shined on a point of the substrate surface previously stripped. Thus, in accordance with one example of the present invention, exposing the same point on the substrate surface to the high intensity femtosecond laser beams of the present invention can be achieved without substantially damaging the substrate surface. Although in the illustrated embodiment the preferred diameter of the spot 101 is about 5 microns, in a different embodiment, the diameter of the spot 101 can be between approximately 250 nanometers and approximately 25 millimeters.

One of ordinary skill in the art must recognize and appreciate that the duration of the femtosecond laser beam pulse can range between approximately one (1) fs to 100,000 fs, a more preferred range of between approximately 30 fs to 150 fs, and the most preferred pulse duration of about 70 fs. In one embodiment, the 70 fs laser beam pulse duration is selected as the 70-femtosecond laser pulses can be easily obtained (e.g., coning the stagnation of the 70-femtosecond-laser beam pulse can be easily achieved due to the properties of the laser amplifier system and compression system). According to one embodiment, the irradiation wavelength depends on whether the discrete wavelength is easily obtainable and whether the discrete wavelength is absorbable by the second layer and not the first layer. One of ordinary skill in the art must appreciate that the irradiation wavelength can range between about 200 nanometers and 1500 nanometers, and most preferably approximately 800 nanometers. Yet further, one of ordinary skill in the art must appreciate that in one embodiment of the present invention, the absorption curve of silicon ranges between about 760 nm and 1160 nm. One of ordinary skill in the art must further recognize and appreciate that the high intensity ultra short laser beam pulse laser system of the present invention can be implemented to remove first layers having a thickness of approximately about one (1) nanometer and 10 microns, and more preferably between approximately one (1) nanometer and, five (5) microns and most preferably between approximately 50 nanometer and two (2) microns. One of ordinary skill in the art must appreciate that a size of the particulate contaminant being removed can range between approximately one (1) nanometer and 10,000 nanometers. In one exemplary embodiment wherein the first layer is an oxide layer, the thickness of the oxide layer being removed can be approximately 0.5 microns (i.e., 5000 Angstroms or 500 nanometers). Of course, one must note that in one embodiment, the layer being removed can have any suitable thickness so long as the coefficient of absorption of the layer being removed is very small.

In one example, an energy threshold of 0.05 J/cm² maybe required for removal of 1 μm thick silicon oxide film using 800 nm irradiation wavelength. If the diameter of the spot is approximately five (5) μm, then 10 nJ per pulse is required to remove the material irradiated by the laser beam spot. The total area from which the film can be removed by one laser pulse depends only on the average power of the incoming beam and the threshold for film removal. According to one embodiment, if the threshold energy density of approximately 0.05 J/cm is implemented using a femtosecond laser system having a power of approximately 0.5 W, a removal speed of 10 cm²/s can be achieved. In such a scenario, in one embodiment, approximately one (1) minute may be needed to achieve complete coverage of the surface of a 12″ wafer at the energy densities above the threshold for film removal.

According to one embodiment of the present invention, the high intensity ultra short laser beam pulse laser system can be implemented to remove films/coatings in discrete locations. For instance, a specific layer of a substrate can be etched using the high intensity ultra short laser beam pluses in discrete locations without having to apply a photoresist material to mark the locations to be removed. In one example, the size of the laser beam spot being shined on the substrate layer to etch a feature can be approximately about 0.1 micron. In another example, the high intensity ultra short laser beam pulses can be implemented to remove material remaining on the beveled edge of the substrate. For instance, the high intensity femtosecond laser system can be implemented to remove material from over the beveled edge of the substrate ranging between approximately hundreds of microns and between tens of microns.

In another embodiment of the present invention, the femtosecond laser system can be integrated into a cleaning system implementing a proximity clean and dry system so as to clean the substrate surfaces. In such an embodiment, after the substrate surfaces have been cleaned and dried using the proximity head, high intensity ultra short laser beam pulse laser system can be implemented to remove edge polymer residues on the front side and/or backside surfaces of the substrate as well as the beveled edge of the substrate surface introduced during the prior processing operations (e.g., etch, lithography, deposition, etc.), etc. For additional information about the proximity vapor clean and dry system, reference can be made to an exemplary system described in the U.S. Pat. No. 6,488,040, issued on Dec. 3, 2002, having inventors John M. de Larios, Mike Ravkin, Glen Travis, Jim Keller, and Wilbur Krusell, and entitled “CAPILLARY PROXIMITY HEADS FOR SINGLE WAFER CLEANING AND DRYING.” This U.S. Patent Application, which is assigned to Lam Research Corporation, the assignee of the subject application, is incorporated herein by reference. Thus, advantageously, the high density ultra short laser beam pulse laser system of the present invention can be implemented to remove particulate contaminants/films/coatings from the substrate surface wherein conventional cleaning techniques (e.g., brush scrubbing, megasonic, etc.) cannot achieve a high degree of precision.

Although for ease of understanding and reference the description of FIGS. 2A-2G refer to the silicon oxide first layer 110 and the silicon second layer 108, one of ordinary skill in the art must appreciate that the high intensity ultra short laser beam pulse laser system of the present invention can be implemented to remove particulate contaminants/films/coatings having different materials than silicon oxide from over the substrate second layer having different materials than silicon. By way of example, the high intensity ultra short laser beam laser system of the present invention can be used to remove a layer of low dielectric constant material from over a silicon nitride layer. In such a model, depending on the spectral properties of the low dielectric constant material, the laser beam wavelength ranging between approximately 100 nanometers and 500 nanometers can be selected so as to be absorbed by the silicon nitride layer and not the low dielectric constant layer. In a different embodiment, the femtosecond laser system of the present invention can be implemented to remove the layer formed over a metal layer. By way of example, the silicon oxide first layer can be removed from over a copper second layer. In the latter scenario, the laser beam wavelength ranging between approximately 500 nanometers and 1400 nanometers is selected so that the laser beam is absorbed by the metal layer and not the silicon oxide layer.

The femtosecond laser system of the present invention can further be implemented at the surface interface of SiC and Si wherein the wavelength of the laser beam can range between about 300 nanometers and 1000 nanometers; Si₃N₄ and Si wherein the wavelength of the laser beam can range between approximately 300 nanometers and 450 nanometers; SiC and Cu wherein the wavelength of the laser beam can range between approximately 500 nanometers and 1400 nanometers; and Si₃N₄ and Cu wherein the wavelength of the laser beam can range between about 500 nanometers and 1400 nanometers.

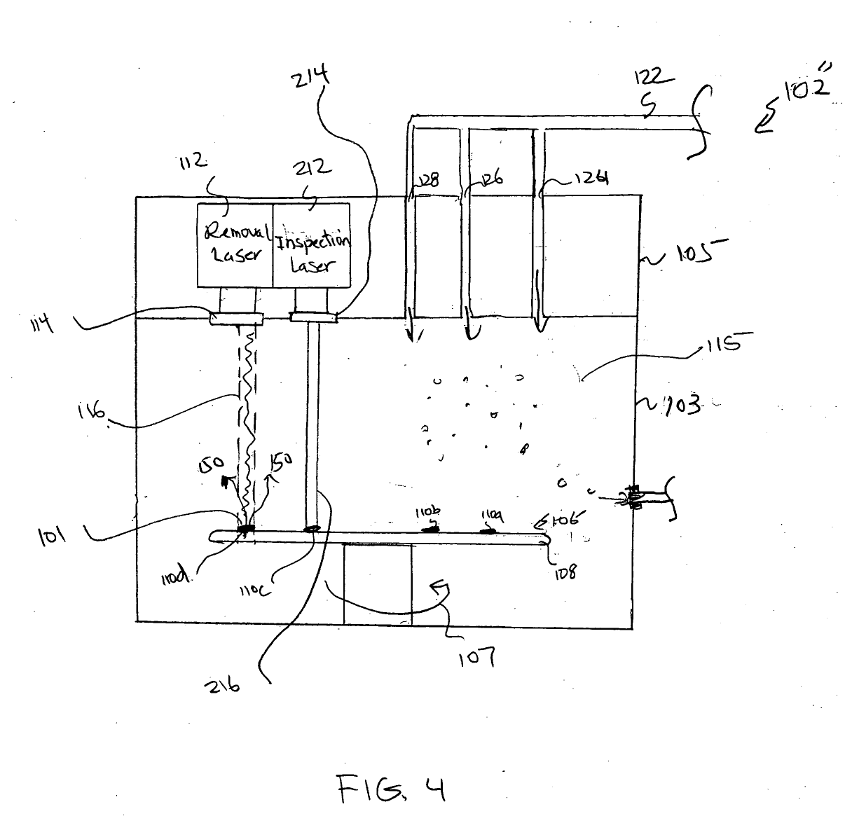

Proceeding to FIG. 3A, reference is made to a simplified cross sectional view of a high intensity ultra short laser beam pulse laser apparatus 102′ implementing diffractive optics, in accordance with one embodiment of the present invention. As can be seen, a laser beam splitter 113 is implemented to split the laser beam issued by the laser system 112 into multiple laser beams 116a-116e. In one example, the energy of the laser beam issued by the laser system 112 may be higher than the amount of energy needed to break the bond between the particulate contaminants/films/coatings and the substrate 106 (e.g., the laser system 112 available for use may support only laser beams with high energies). As can be seen, each laser beam 116a-116c is shown to be associated with a respective mirror 112′a-114′e. In this manner, laser beams 116a-116e are shined onto the first layer 110 on respective spots 101′a-101′e. As can be seen, laser beams 116a-116e have traveled through the first layer 110 and are ultimately absorbed in the second layer 108. In this manner, portions 136 of the first layer 110 are ultimately evaporated, as the bonds between the portions 136 and the second layer 108 are broken.

FIG. 3B is a simplified top view of the substrate 106 being processed using the diffractive laser beams 116a-116e shown in FIG. 3A, in accordance with one embodiment of the present invention. As can be seen, the multiple laser beams 116a-116e are applied onto the substrate 106 collectively such that the spots 101′a-101′e are defined adjacent to one another and aligned in a substantially straight line. In this manner, the multiple laser beams 116a-116e remove the portions 136a-136e of the first layer 110 in a spiral manner. However, while removed portions 136′a-136′e do not overlap, removed portions 136″a-136″e are shown to have overlapping regions. However, as the intensity of the laser beams 116a-116e are lower than the intensity of the beam issued by the laser and the pulse durations are very short, applying the laser beams 116a-116e multiple times on the same point on the substrate surface cannot damage the substrate surface. One of ordinary skill in the art must appreciate that although in the embodiment shown in FIGS. 3A-3B the multiple laser beams 116a-116e are shown to have been shined onto the substrate perpendicularly, in another embodiment, the multiple laser beams 116a-116e can be shined onto the substrate surface using a wide range of angles. In one example, the laser beams 116a-116e can be shined onto the substrate at the angle ranging between about 30 degrees and 90 degrees. Additionally, one of ordinary skill in the art must appreciate that the splitter 113 can be used to split the laser beam issued by the laser system into any number of laser beams so long as the resulting laser beams have adequate energy to break the bond between the first layer and the second layer. By way of example, if the laser beam energy is greater than approximately 10 nJ/pulse, the laser beam can be spilt into multiple beams to achieve better utilization of the available energy using.

Furthermore, depending on the application, the angle of the beams with the substrate surface can be controlled by the system control 118. Additionally, depending on the application, the size of the spot size can be minimized or the substrate coverage can be maximized using the system control 118. In another example, the system control 118 can be implemented to set the system for optimization for specific properties of the substrate layers and applications. According to one embodiment, to maximize throughput, the system control 118 may maximize the number of laser beams being shined onto the substrate.

FIG. 4 is a simplified cross sectional view of an integrated laser surface inspection and particulate contaminant/film/coating removal apparatus 102″ implemented to inspect and locally remove defects from over substrate surface, in accordance with one embodiment of the present invention. As can be seen, a top component 105 of the integrated apparatus 102″ houses an inspection laser 212 and a removal laser 112. In one example, the inspection laser 212 is implemented to find particulate contaminants 10a-10d from over the substrate 106′ while the removal laser 112 can be implemented to remove the found particulate contaminants 110a-110d. One must note that the removal laser 112 and the scanning laser 212 are combined so as to avoid scanning and inspecting the entire substrate surface. In one example, the substrate surface is scanned by a laser beam 216 issued by the inspection laser 212 so as to find particulate contaminants 110a-110d. For instance, when the particulate contaminants 110a-110d have been located, the system control 118 directs the stage 104 to move in a manner so as to place the spot 101 on the location of each of the particulate contaminants detected. In one example, the control system 118 uses a control algorithm to detect the location of the defects. Once located, as described in more detail with respect to FIGS. 2A-2G, the removal laser 112 can be implemented to remove the particulate contaminants 110a-110d by shinning ultra short pulse laser beam 116 onto the specific particulate contaminant (in the illustrated embodiment, particulate contaminant 110d), so as to break the bond between the particulate contaminant and the substrate surface at the spot 101 wherein the laser beam 116 is shinning.

According to one example, inspection and local removal of particulate contaminants of the apparatus 102″ can be implemented to clean the substrate backside. Specifically, the apparatus 102″ can be implemented to remove particulate contaminants and materials deposited around edges of scratches formed in the substrate backside. Once located, the particulate contaminants are ultimately evaporated and removed from over the substrate backside and into the chamber 103, which are ultimately, expelled using adequate flow of inert gases (e.g., nitrogen, argon, helium, a proprietary reactive gas mixture, etc.).

According to one embodiment of the present invention, the femtosecond laser system of the present invention in a clustered substrate processing system. For instance, after a substrate has been pre-processed in an etching chamber, a chemical vapor deposition system, a chemical mechanical polishing (CMP) system, etc., the substrate surfaces can be prepared in the femtosecond laser system of the present invention.

Yet further, in one exemplary implementation, the femtosecond laser system of the present invention can be implemented in a clustered substrate preparation apparatus that may be controlled in an automated way by a control station. For instance, the clustered substrate preparation apparatus may include a sender station, a femtosecond laser module, and a receiver station. Broadly stated, substrates initially placed in the sender station are delivered, one-at-a-time, to the femtosecond laser module. After being prepared, the substrates are then delivered to the receiver station for being stored temporarily. One of ordinary skill in the art must appreciate that in one embodiment, the clustered preparation apparatus can be implemented to carry out a plurality of different substrate preparation operations (e.g., cleaning, etching, etc.).

Although the foregoing invention has been described in some detail for purposes of clarity of understanding, it will be apparent that certain changes and modifications may be practiced within the scope of the appended claims. For example, the embodiments of the present invention can be implemented to clean and prepare any substrate having varying sizes and shapes such as those employed in the manufacture of semiconductor devices, flat panel displays, hard drive discs, flat panel devices, and the like. Additionally, the present embodiments are to be considered as illustrative and not restrictive, and the invention is not to be limited to the details given herein, but may be modified within the scope and equivalents of the appended claims.

What is claimed is:

1. A substrate preparation method, the method comprising:
providing a substrate to be prepared, the substrate having a first layer and a second layer, the first layer configured to be removed from over the second layer;
determining an energy frequency, the energy frequency,configured to be absorbed by the second layer while penetrating through the first layer transparently;
applying energy having the determined energy frequency onto the first layer so as to disrupt a bond between the first layer and the second layer at a location of application of the energy; and
removing a portion of the first layer defined at the location of application of the energy.

2. The method as recited in claim 1, the method further comprising:
absorbing of the energy by the second layer at the location of application of the energy; and
creating an energy wave at a bond interface between the first layer and the second layer at the location of application of the energy.

3. The method as recited in claim 1 wherein the energy is applied onto the first layer for an ultra short time duration.

4. The method as recited in claim 3 wherein the ultra short time duration is in the order of femtoseconds.

5. The method as recited in claim 1, wherein the removed portion of the first layer defined at the location of application of the energy is evaporated.

6. The method as recited in claim 5, wherein removing of the removed portion starts at a bond interface between the first layer and the second layer at the location of application of the energy.

7. The method of claim 1, the method further comprising:
translationally rotating the substrate.

8. The method as recited in claim 1, wherein the first layer is silicon oxide and the second layer is silicon, the first layer is a low constant dielectric material and the second layer is silicon nitride, the first layer is silicon oxide and the second layer is copper, the first layer is SiC and the second layer is silicon, the first layer is Si₃N₄ and the second layer is silicon, the first layer is SiC and the second layer is Si₃N₄, the first layer is SiC and the second layer is copper, or the first layer is Si₃N₄ and the second layer is copper.

9. A substrate preparation apparatus, the apparatus comprising:
an energy source capable of emitting energy onto a substrate to be prepared, the energy being emitted in a femtosecond pulse duration, the substrate having a first layer and a second layer, the first layer configured to be removed from over the second layer, the energy configured to have an energy frequency capable of being absorbed by the second layer while transparently penetrating through the first layer; and
a support component configured to support the substrate to be prepared as energy is emitted onto the first layer of the substrate,
wherein absorption of the energy by the second layer generates an energy wave capable of breaking a bond between the first layer and the second layer at a location of application of the energy so as to remove a portion of the first layer at the location of the application of the energy.

10. The apparatus as recited in claim 9, wherein the support component is configured to translationally rotate.

11. The apparatus as recited in claim 9, wherein the energy source is a laser system.

12. The apparatus as recited in claim 9, wherein the energy source is configured to scan the substrate surface.

13. The apparatus as recited in claim 11, wherein the pulse duration of the energy being emitted is approximately 70 femtoseconds.

14. The apparatus as recited in claim 13, wherein the first layer is silicon oxide and the second layer is silicon, the first layer is a low constant dielectric material and the second layer is silicon nitride, the first layer is silicon oxide and the second layer is copper, the first layer is SiC and the second layer is silicon, the first layer is Si₃N₄ and the second layer is silicon, the first layer is SiC and the second layer is Si₃N₄, the first layer is SiC and the second layer is copper, or the first layer is Si₃N₄ and the second layer is copper.

15. The apparatus as recited in claim 9, the apparatus further comprising:
an energy splitting component configured to split the energy into energy sub-portions.

16. The apparatus as recited in claim 9, the apparatus further comprising:
an inspection source configured to scan the substrate so as to locate particulate a defect.

17. A substrate preparation method, the method comprising:
determining an energy frequency configured to be absorbed by a substrate surface while transparently penetrating through a particulate contaminant adhered to the substrate surface; and
applying energy having the determined energy frequency onto the particulate contaminant so as to disrupt a bond between the particulate contaminant and the substrate surface.

18. The method as recited in claim 17, the method further comprising:
removing the particulate contaminant starting at a bond interface of the particulate contaminant and the substrate surface.

19. The method as recited in claim 17, the method further comprising:
absorbing of the energy by the second layer at the location of application of the energy; and
creating an energy wave at a bond interface between the particulate contaminant and the second layer at the location of application of the energy.

20. The method as recited in claim 17, wherein the energy is applied onto the particulate contaminant for an ultra short time duration.
